(19) United States
(12) Patent Application Publication
(10) Pub. No.: US 2026/0045923 A1
(43) Pub. Date: Feb. 12, 2026

(54) DIFFERENTIAL SIGNAL GENERATION CIRCUIT

(71) Applicant: Nuvoton Technology Corporation, Hsinchu Science Park (TW)

(72) Inventor: Cheng-Tao LI, Hsinchu Science Park (TW)

(21) Appl. No.: 19/276,369

(22) Filed: Jul. 22, 2025

(30) Foreign Application Priority Data
Aug. 9, 2024 (TW) 113129842

(51) Int. Cl. H03F 3/45; H03F 1/02

(52) U.S. Cl. CPC H03F 3/4521; H03F 1/0266; H03F 3/45273; H03F 3/45681; H03F 2200/129

(57) ABSTRACT

A differential signal generation circuit is provided. A PMOS transistor pair provides a first current to a current modulator circuit. A first current control circuit is coupled to the PMOS transistor pair in parallel. When the PMOS transistor pair is turned off, the first current control circuit provides the first current to the current adjustment circuit. An NMOS transistor pair provides a second current to the current modulator circuit. A second current control circuit is coupled to the NMOS transistor pair in parallel. When the NMOS transistor pair is turned off, the second current control circuit provides the second current to the current modulator circuit. The current modulator circuit sets the static current of a first output terminal to be equal to the static current of a second output terminal.

### CROSS REFERENCE TO RELATED APPLICATIONS

This Application claims priority of Taiwan Patent Application No. 113129842, filed on Aug. 9, 2024, the entirety of which is incorporated by reference herein.

### BACKGROUND OF THE INVENTION

### Field of the Invention

The invention relates to a differential signal generation circuit, and more particularly it relates to a differential signal generation circuit with a wide range of input voltages.

### Description of the Related Art

In conventional differential operational amplifiers, an NMOS transistor pair or a PMOS transistor pair is usually used to receive input signals. However, the voltages of the input signals are limited by the threshold voltage of the NMOS transistor pair or the PMOS transistor pair. Taking the NMOS transistor pair as an example, when the voltages of the input signals are lower than the threshold voltage of the NMOS transistor pair, the NMOS transistor pair will not work.

### BRIEF SUMMARY OF THE INVENTION

In accordance with an embodiment, a differential signal generation circuit comprises a first current source, a current modulator circuit, a PMOS transistor pair, a first current control circuit, a second current source, NMOS transistor pair, a second current control circuit, a third current source, a fourth current source, a fifth current source, a sixth current source, and a common-mode feedback (CMFB) circuit. The first current source receives a first operation voltage to generate a first current. The current modulator circuit adjusts the current of a first output terminal and the current of a second output terminal. The PMOS transistor pair is coupled between the first current source and the current modulator circuit to provide the first current to the current modulator circuit and receives a first input signal and a second input signal. The first current control circuit is coupled to the PMOS transistor pair in parallel. In response to the PMOS transistor pair being turned off, the first current control circuit transmits the first current to the current modulator circuit. The second current source receives a second operation voltage to generate a second current. The NMOS transistor pair is coupled between the current modulator circuit and the second current source to provide the second current to the current modulator circuit and receives the first input signal and the second input signal. The second current control circuit is coupled to the NMOS transistor pair in parallel. In response to the NMOS transistor pair being turned off, the second current control circuit transmits the second current to the current modulator circuit. The third current source receives the first operation voltage and is coupled to the first output terminal. The fourth current source is coupled to the first output terminal and receives the second operation voltage. The fifth current source receives the first operation voltage and is coupled to the second output terminal. The sixth current source is coupled to the second output terminal and receives the second operation voltage. The CMFB circuit adjusts the third current source or the fourth current source based on the voltage of the first output terminal and the common-mode voltage. It also adjusts the fifth current source or the sixth current source based on the voltage of the second output terminal and the common-mode voltage. In response to the first current control circuit being in operation, the current modulator circuit provides a first sub-current to the first output terminal and provides a second sub-current to the second output terminal. In response to the second current control circuit being in operation, the current modulator circuit provides a third sub-current to the first output terminal and provides a fourth sub-current to the second output terminal. The sum of the first sub-current and the second sub-current is equal to the first current. The sum of the third sub-current and the fourth sub-current is equal to the second current.

### BRIEF DESCRIPTION OF THE DRAWINGS

The present invention can be more fully understood by reading the subsequent detailed description and examples with references made to the accompanying drawings, wherein:

FIG. 1 is a schematic diagram of an exemplary embodiment of a differential signal generation circuit based on various aspects of the present disclosure.

FIG. 2 is a schematic diagram of an exemplary embodiment of current control circuits and a current modulator circuit based on various aspects of the present disclosure.

FIG. 3 is a schematic diagram of another exemplary embodiment of the current modulator circuit based on various aspects of the present disclosure.

FIG. 4 is a schematic diagram of an exemplary embodiment of a common-mode feedback circuit based on various aspects of the present disclosure.

### DETAILED DESCRIPTION OF THE INVENTION

The present invention will be described with respect to particular embodiments and with reference to certain drawings, but the invention is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the invention.

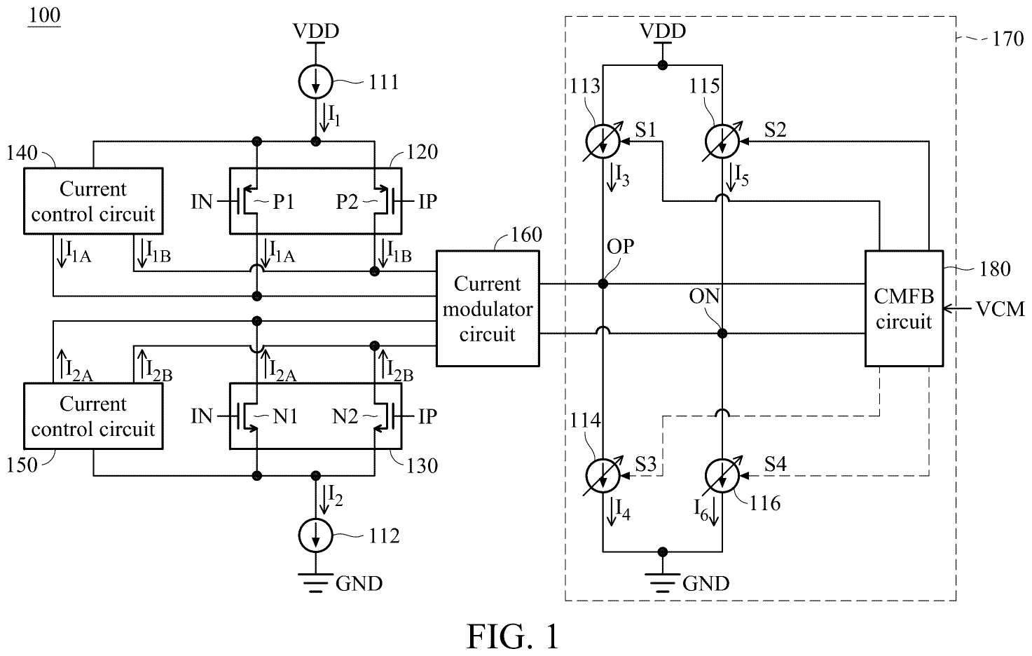

FIG. 1 is a schematic diagram of an exemplary embodiment of a differential signal generation circuit based on various aspects of the present disclosure. The differential signal generation circuit 100 comprises current sources 111 and 112, a PMOS transistor pair 120, an NMOS transistor pair 130, current control circuits 140 and 150, a current modulator circuit 160, and an output-stage circuit 170. The current source 111 receives an operation voltage VDD and generates a current I₁. The current source 112 receives an operation GND and generates a current I₂. The operation voltage GND is lower than the operation voltage VDD. In one embodiment, the operation voltage GND is a ground voltage, such as 0V. In another embodiment, the operation voltage VDD is about 5V.

The PMOS transistor pair 120 is coupled between the current source 111 and the current modulator circuit 160 to provide the current I₁ to the current modulator circuit 160 and receives input signals IN and IP. In this embodiment, the PMOS transistor pair 120 comprises PMOS transistors P1 and P2. The gate of the PMOS transistor P1 receives the input signal IN. The source of the PMOS transistor P1 is coupled to the current source 111. The drain of the PMOS transistor P1 is coupled to the current modulator circuit 160. The gate of the PMOS transistor P2 receives the input signal IP. The source of the PMOS transistor P2 is coupled to the current source 111. The drain of the PMOS transistor P2 is coupled to the current modulator circuit 160. When the PMOS transistor P1 is turned on, the PMOS transistor P1 provides a sub-current I_{1A} to the current modulator circuit 160. When the PMOS transistor P2 is turned on, the PMOS transistor P2 provides a sub-current I_{1B} to the current modulator circuit 160. The sum of the sub-current I_{1A} and the sub-current I_{1B} are equal to the current I₁.

The NMOS transistor pair 130 is coupled between the current modulator circuit 160 and the current source 112 to provide the current I₂ to the current modulator circuit 160 and receives the input signals IN and IP. In this embodiment, the NMOS transistor pair 130 comprises NMOS transistors N1 and N2. The gate of the NMOS transistor N1 receives the input signal IN. The source of the NMOS transistor N1 is coupled to the current source 112. The drain of the NMOS transistor N1 is coupled to the current modulator circuit 160. The gate of the NMOS transistor N2 receives the input signal IP. The source of the NMOS transistor N2 is coupled to the current source 112. The drain of the NMOS transistor N2 is coupled to the current modulator circuit 160. When the NMOS transistor N1 is turned on, the NMOS transistor N1 provides a sub-current I_{2A} to the current modulator circuit 160. When the NMOS transistor N2 is turned on, the NMOS transistor N2 provides a sub-current I_{2B} to the current modulator circuit 160. In this embodiment, the sum of the sub-current I_{2A} and the sub-current I_{2B} are equal to the current I₂.

The current control circuit 140 is coupled to the PMOS transistor pair 120 in parallel. When the PMOS transistor pair 120 does not operate, the current control circuit 140 replaces the PMOS transistor pair 120 to provide the sub-current I_{1A} and the sub-current I_{1B} to the current modulator circuit 160. However, when the PMOS transistor pair 120 operates, the current control circuit 140 stops providing the sub-current I_{1A} and the sub-current I_{1B}.

The current control circuit 150 is coupled to the NMOS transistor pair 130 in parallel. When the NMOS transistor pair 130 does not operate, the current control circuit 150 replaces the NMOS transistor pair 130 to provide the sub-current I_{2A} and the sub-current I_{2B} to the current modulator circuit 160. However, when the NMOS transistor pair 130 operates, the current control circuit 150 stops providing the sub-current I_{2A} and the sub-current I_{2B}.

The current modulator circuit 160 controls the current passing through the output terminal OP and the current passing through the output terminal ON based on the sub-current ILA, the sub-current I_{1B}, the sub-current I_{2A}, and the sub-current I_{2B}. For example, when the PMOS transistor pair 120 operates, the current modulator circuit 160 provides the sub-current I_{1A} generated by the PMOS transistor pair 120 to the output terminal OP and provides the sub-current I_{1B} generated by the PMOS transistor pair 120 to the output terminal ON. However, when the current control circuit 140 replaces the PMOS transistor pair 120 to provides the sub-current I_{1A} and the sub-current I_{1B}, the current modulator circuit 160 provides the sub-current I_{1A} generated by the current control circuit 140 to the output terminal OP and provides the sub-current I_{1B} generated by the current control circuit 140 to the output terminal ON.

In some embodiments, when the NMOS transistor pair 130 operates, the current modulator circuit 160 provides the sub-current I_{2A} generated by the NMOS transistor pair 130 to the output terminal OP and provides the sub-current I_{2B} generated by the NMOS transistor pair 130 to the output terminal ON. However, when the current control circuit 150 replaces the NMOS transistor pair 130 to provides the sub-current I_{2A} and the sub-current I_{2B}, the current modulator circuit 160 provides the sub-current I_{2A} generated by the current control circuit 150 to the output terminal OP and provides the sub-current I_{2B} generated by the current control circuit 150 to the output terminal ON.

The operation of the PMOS transistor pair 120 and the operation of the NMOS transistor pair 130 are associated with the input signal IN and the input signal IP. For example, assume that the operation voltage VDD is 5V, the operation voltage GND is 0V, and the threshold voltages of the PMOS transistor P1, the PMOS transistor P2, the NMOS transistor N1 and the NMOS transistor N2 are 1V. When the input signal IN and the input signal IP do not have data components, the input signal IN and the input signal IP are equal to a digital voltage.

When the digital voltage is higher than a first threshold value (e.g., 4.1V), since the voltage difference between the gate and the source of the PMOS transistor P1 is lower than the threshold voltage of the PMOS transistor P1 and the voltage difference between the gate and the source of the PMOS transistor P2 is lower than the threshold voltage of the PMOS transistor P2, the PMOS transistor P1 and the PMOS transistor P2 are turned off. At this time, the current control circuit 140 operates. Therefore, the current modulator circuit 160 receives the sub-current I_{1A} and the sub-current I_{1B} from the current control circuit 140. Since the voltage difference between the gate and the source of the NMOS transistor N1 is higher than the threshold voltage of the NMOS transistor N1 and the voltage difference between the gate and the source of the NMOS transistor N2 is higher than the threshold voltage of the NMOS transistor N2, the NMOS transistor N1 and the NMOS transistor N2 are turned on. Therefore, the current modulator circuit 160 receives the sub-current I_{2A} and the sub-current I_{2B} from the NMOS transistor pair 130. At this time, the current control circuit 150 does not operate.

When the digital voltage is lower than a second threshold value (e.g., 0.9V), since the voltage difference between the gate and the source of the NMOS transistor N1 is lower than the threshold voltage of the NMOS transistor N1 and the voltage difference between the gate and the source of the NMOS transistor N2 is lower than the threshold voltage of the NMOS transistor N2, the NMOS transistor N1 and the NMOS transistor N2 are turned off. At this time, the current control circuit 150 operates. Therefore, the current modulator circuit 160 receives the sub-current I_{2A} and the sub-current I_{2B} from the current control circuit 150. Since the voltage difference between the gate and the source of the PMOS transistor P1 is higher than the threshold voltage of the PMOS transistor P1 and the voltage difference between the gate and the source of the PMOS transistor P2 is higher than the threshold voltage of the PMOS transistor P2, the PMOS transistor P1 and the PMOS transistor P2 are turned on. Therefore, the current modulator circuit 160 receives the sub-current I_{1A} from the PMOS transistor P1 and the sub-current I_{1B} from the PMOS transistor P2. At this time, the current control circuit 140 does not operate.

When the digital voltage is lower than the first threshold value (e.g., 4.1V) and higher than the second threshold value (e.g., 0.9V), since the voltage difference between the gate and the source of the PMOS transistor P1 is higher than the threshold voltage of the PMOS transistor P1 and the voltage difference between the gate and the source of the PMOS transistor P2 is higher than the threshold voltage of the PMOS transistor P2, the PMOS transistor P1 and the PMOS transistor P2 are turned on. The current modulator circuit 160 receives the sub-current I_{1A} and the sub-current I_{1B} from the PMOS transistor pair 120. At this time, since the voltage difference between the gate and the source of the NMOS transistor N1 is higher than the threshold voltage of the NMOS transistor N1 and the voltage difference between the gate and the source of the NMOS transistor N2 is higher than the threshold voltage of the NMOS transistor N2, the NMOS transistor N1 and the NMOS transistor N2 are turned on. The current modulator circuit 160 receives the sub-current I_{2A} and the sub-current I_{2B} from the NMOS transistor pair 130. At this time, the current control circuit 140 and current control circuit 150 do not operate.

The output-stage circuit 170 adjusts the voltage of the output terminal OP and the voltage of the output terminal ON based on the voltage of the output terminal OP, the voltage of the output terminal ON, and a common-mode voltage VCM so that the voltage of the output terminal OP and the voltage of the output terminal ON are equal to the common-mode voltage VCM when the input signal IN and the input signal IP do not have data components. In one embodiment, the output-stage circuit 170 comprises a common-mode feedback (CMFB) circuit 180 and current sources 113-116.

The CMFB circuit 180 is coupled to the output terminal OP and the output terminal ON and receives the common-mode voltage VCM. In one embodiment, the CMFB circuit 180 generates adjustment signals S1 and S2 based on the voltage of the output terminal OP and the voltage of the output terminal ON. In another embodiment, the CMFB circuit 180 generates adjustment signals S3 and S4 based on the voltage of the output terminal OP, the voltage of the output terminal ON, and the common-mode voltage VCM. In some embodiments, when the CMFB circuit 180 generates the adjustment signals S1 and S2, the CMFB circuit 180 does not generate the adjustment signals S3 and S4. When the CMFB circuit 180 generates the adjustment signals S3 and S4, the CMFB circuit 180 does not generate the adjustment signals S1 and S2.

The current source 113 receives the operation voltage VDD and is coupled to the output terminal OP. In one embodiment, the current source 113 generates and adjusts the current I₃ based on the adjustment signal S1. In this case, the current source 113 is a variable current source. In another embodiment, the current source 113 is a fixed current source. In this case, the CMFB circuit 180 does not generate the adjustment signal S1. The CMFB circuit 180 uses the adjustment signal S3 to adjust the current passing through the output terminal OP and further control the voltage of the output terminal OP.

The current source 114 is coupled to the output terminal OP and receives the operation voltage GND. In one embodiment, the current source 114 generates and adjusts the current I₄ based on the adjustment signal S3. In this case, the current source 114 is a variable current source. In another embodiment, the current source 114 is a fixed current source. In this case, the CMFB circuit 180 does not generate the adjustment signal S3. The CMFB circuit 180 uses the adjustment signal S1 to adjust the current passing through the output terminal OP and further control the voltage of the output terminal OP.

The current source 115 receives the operation voltage VDD and is coupled to the output terminal ON. In one embodiment, the current source 115 generates and adjusts the current I₅ based on the adjustment signal S2. In this case, the current source 115 is a variable current source. In another embodiment, the current source 115 is a fixed current source. In this case, the CMFB circuit 180 does not generate the adjustment signal S2. The CMFB circuit 180 uses the adjustment signal S4 to adjust the current passing through the output terminal ON and further control the voltage of the output terminal ON.

The current source 116 is coupled to the output terminal ON and receives the operation voltage GND. In one embodiment, the current source 116 generates and adjusts the current I₆ based on the adjustment signal S4. In this case, the current source 116 is a variable current source. In another embodiment, the current source 116 is a fixed current source. In this case, the CMFB circuit 180 does not generate the adjustment signal S4. The CMFB circuit 180 uses the adjustment signal S2 to adjust the current passing through the output terminal ON and further control the voltage of the output terminal ON.

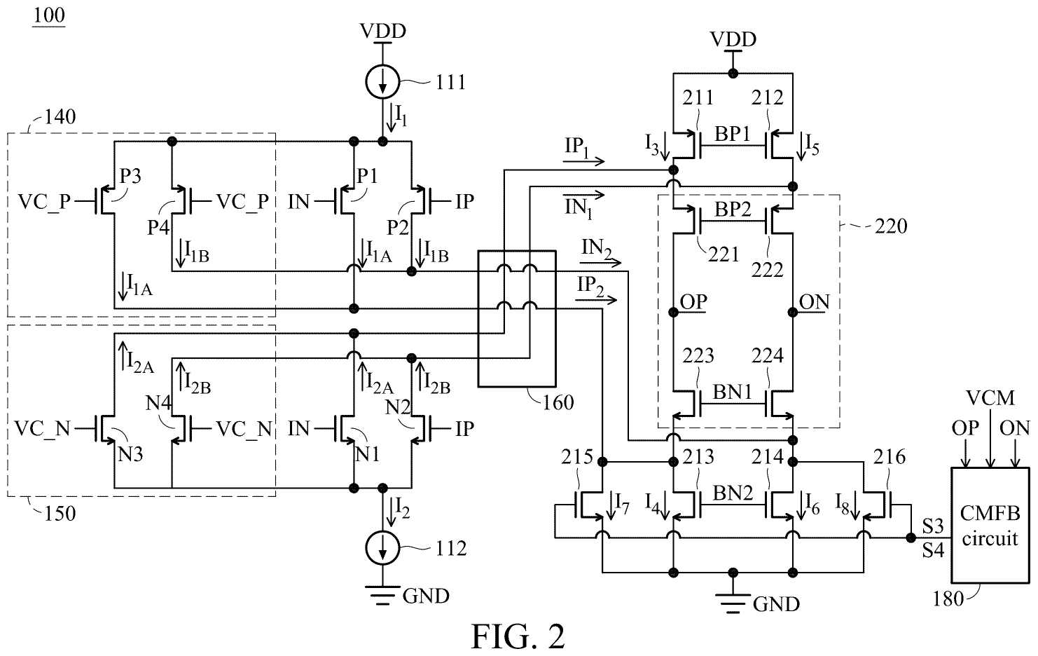

FIG. 2 is a schematic diagram of an exemplary embodiment of the current control circuit 140, the current control circuit 150, and the current modulator circuit 160 based on various aspects of the present disclosure. The current control circuit 140 comprises PMOS transistors P3 and P4. The gate of the PMOS transistor P3 receives a control voltage VC_P. The source of the PMOS transistor P3 is coupled to the current source 111. The drain of the PMOS transistor P3 is coupled to the drain of the PMOS transistor P1. The gate of the PMOS transistor P4 receives the control voltage VC_P. The source of the PMOS transistor P4 is coupled to the current source 111. The drain of the PMOS transistor P4 is coupled to the drain of the PMOS transistor P2.

In one embodiment, the control voltage VC_P is lower than the first threshold value (e.g., 4.1V). Assume that the control voltage VC_P is 3.9V. In this case, when the input signals IN and IP do not have data components and the voltages of the input signals IN and IP are higher than the first threshold value, the PMOS transistors P1 and P2 are turned off and the PMOS transistors P3 and P4 are turned on. Therefore, the PMOS transistor P3 provides the sub-current I_{1A}, and the PMOS transistor P4 provides the sub-current I_{1B}. When the voltages (e.g., 3.8V) of the input signals IN and IP are lower than the first threshold value, since the voltage difference between the gate and the source of the PMOS transistor P1 is higher than the voltage difference between the gate and the source of the PMOS transistor P3 and the voltage difference between the gate and the source of the PMOS transistor P2 is higher than the voltage difference between the gate and the source of the PMOS transistor P4, the PMOS transistors P1 and P2 are turned on and the PMOS transistors P3 and P4 are turned off. At this time, the PMOS transistor P1 provides the sub-current I_{1A}, and the PMOS transistor P2 provides the sub-current I_{1B}.

The current control circuit 150 comprises NMOS transistors N3 and N4. The gate of the NMOS transistor N3 receives a control voltage VC_N. The source of the NMOS transistor N3 is coupled to the current source 112. The drain of the NMOS transistor N3 is coupled to the drain of the NMOS transistor N1. The gate of the NMOS transistor N4 receives the control voltage VC_N. The source of the NMOS transistor N4 is coupled to the current source 112. The drain of the NMOS transistor N4 is coupled to the drain of the NMOS transistor N2.

In one embodiment, the control voltage VC_N is lower than the control voltage VC_P and higher than the second threshold value (e.g., 0.9V). Assume that the control voltage VC_N is 1.1V. In this case, when the input signals IN and IP do not have data components and the voltages of the input signals IN and IP are lower than the second threshold value, the NMOS transistors N1 and N2 are turned off and the NMOS transistors N3 and N4 are turned on. Therefore, the NMOS transistor N3 provides the sub-current I_{2A}, and the NMOS transistor N4 provides the sub-current I_{2B}. When the voltages (e.g., 1.2V) of the input signals IN and IP are higher than the second threshold value, since the voltage difference between the gate and the source of the NMOS transistor N1 is higher than the voltage difference between the gate and the source of the NMOS transistor N3 and the voltage difference between the gate and the source of the NMOS transistor N2 is higher than the voltage difference between the gate and the source of the NMOS transistor N4, the NMOS transistors N1 and N2 are turned on and the NMOS transistors N3 and N4 are turned off. At this time, the NMOS transistor N1 provides the sub-current I_{2A}, and the NMOS transistor N2 provides the sub-current I_{2B}.

The current modulator circuit 160 provides the sub-current I_{2A} as the current IP₁ and provides the sub-current I_{2B} as the current IN₁. The sub-current I_{2A} and the sub-current I_{2B} may be provided from the NMOS transistors N1 and N2 or from the NMOS transistors N3 and N4. Furthermore, the current modulator circuit 160 provides the sub-current I_{1A} as the current IP₂ and provides the sub-current I_{1B} as the current IN₂. The sub-current I_{1A} and the sub-current I_{1B} may be provided from the PMOS transistors P1 and P2 or from the PMOS transistors P3 and P4.

In one embodiment, the differential signal generation circuit 100 further comprises PMOS transistors 211 and 212, and NMOS transistors 213 and 214. The PMOS transistor 211 serves as the current source 113 of FIG. 1 to provide the current I₃. The gate of the PMOS transistor 211 receives a control signal BP1. The source of the PMOS transistor 211 receives the operation voltage VDD. The drain of the PMOS transistor 211 receives the current IP₁. In this case, when the PMOS transistor 211 is turned on, the current I₃ passes through the PMOS transistor 211.

The PMOS transistor 212 serves as the current source 115 of FIG. 1 to provide the current I₅. The gate of the PMOS transistor 212 receives the control signal BP1. The source of the PMOS transistor 212 receives the operation voltage VDD. The drain of the PMOS transistor 212 receives the current IN₁. In this case, when the PMOS transistor 212 is turned on, the current I₅ passes through the PMOS transistor 212.

The NMOS transistor 213 serves as the current source 114 of FIG. 1 to provide the current I₄. The gate of the NMOS transistor 213 receives a control signal BN2. The source of the NMOS transistor 213 receives the operation voltage GND. The drain of the NMOS transistor 213 receives the current IP₂. In this case, when the NMOS transistor 213 is turned on, the current I₄ passes through the NMOS transistor 213.

The NMOS transistor 214 serves as the current source 116 of FIG. 1 to provide the current I₆. The gate of the NMOS transistor 214 receives the control signal BN2. The source of the NMOS transistor 214 receives the operation voltage GND. The drain of the NMOS transistor 214 receives the current IN₂. In this case, when the NMOS transistor 214 is turned on, the current I₆ passes through the NMOS transistor 214.

In some embodiments, the differential signal generation circuit 100 further comprises a shielding circuit 220. The shielding circuit 220 comprises PMOS transistors 221 and 222, and NMOS transistors 223 and 224. The PMOS transistor 221 is coupled between the PMOS transistor 211 and the output terminal OP. In this case, the gate of the PMOS transistor 221 receives a control signal BP2. The source of the PMOS transistor 221 is coupled to the drain of the PMOS transistor 211. The drain of the PMOS transistor 221 is coupled to the output terminal OP.

The PMOS transistor 222 is coupled between the PMOS transistor 212 and the output terminal ON. In this case, the gate of the PMOS transistor 222 receives the control signal BP2. The source of the PMOS transistor 222 is coupled to the drain of the PMOS transistor 212. The drain of the PMOS transistor 222 is coupled to the output terminal ON.

The NMOS transistor 223 is coupled between the output terminal ON and the NMOS transistor 213. In this case, the gate of the NMOS transistor 223 receives a control signal BN1. The source of the NMOS transistor 223 is coupled to the drain of the NMOS transistor 213. The drain of the NMOS transistor 223 is coupled to the output terminal OP.

The NMOS transistor 224 is coupled between the output terminal ON and the NMOS transistor 214. In this case, the gate of the NMOS transistor 224 receives the control signal BN1. The source of the NMOS transistor 224 is coupled to the drain of the NMOS transistor 214. The drain of the NMOS transistor 224 is coupled to the output terminal ON.

In other embodiments, the differential signal generation circuit 100 further comprises NMOS transistors 215 and 216. The NMOS transistor 215 serves as a current source to provide the current I₇. In this case, the gate of the NMOS transistor 215 is coupled to the CMFB circuit 180 to receive the adjustment signal S3. The drain of the NMOS transistor 215 is coupled to the drain of the NMOS transistor 2123. The source of the NMOS transistor 215 receives the operation voltage GND.

In one embodiment, the CMFB circuit 180 generates the adjustment signal S3 based on the voltage of the output terminal OP and the common-mode voltage VCM. For example, when the voltage of the output terminal OP is higher than the common-mode voltage VCM, the CMFB circuit 180 generates the adjustment signal S3 to reduce the current I₇ which passes through the NMOS transistor 215. When the voltage of the output terminal OP is lower than the common-mode voltage VCM, the CMFB circuit 180 generates the adjustment signal S3 to increase the current I₇ which passes through the NMOS transistor 215.

In this embodiment, the NMOS transistor 216 serves as another current source to provide the current I₈. In this case, the gate of the NMOS transistor 216 is coupled to the CMFB circuit 180 to receive the adjustment signal S4. The drain of the NMOS transistor 216 is coupled to the drain of the NMOS transistor 214. The source of the NMOS transistor 216 receives the operation voltage GND.

In one embodiment, the CMFB circuit 180 generates the adjustment signal S4 based on the voltage of the output terminal ON and the common-mode voltage VCM. For example, when the voltage of the output terminal ON is higher than the common-mode voltage VCM, the CMFB circuit 180 generates the adjustment signal S4 to reduce the current I₈ which passes through the NMOS transistor 216. When the voltage of the output terminal ON is lower than the common-mode voltage VCM, the CMFB circuit 180 generates the adjustment signal S4 to increase the current I₈ which passes through the NMOS transistor 216. In some embodiments, the adjustment signal S4 is the same as the adjustment signal S3.

In some embodiments, when the input signals IN and IP do not have data components and the voltages of the input signals IN and IP are higher than the first threshold value, the PMOS transistor pair 120 does not operate and the NMOS transistor pair 130 operates. At this time, the current control circuit 140 replaces the PMOS transistor pair 120 to provide the sub-currents I_{1A} and I_{1B} to the current modulator circuit 160. The current modulator circuit 160 provides the sub-current I_{1A} as the current IP₂, provides the sub-current I_{1B} as the current IN₂, provides the sub-current I_{2A} as the current IP₁, and provides the sub-current I_{2B} as the current IN₁. At this time, the current flowing into the output terminal OP is the sum of the currents I₃ and IP₁. Since the current modulator circuit 160 provides the current IP₂, the current flowing out of the output terminal OP is the sum of the currents IP₂, I₄, and I₇. In this case, the sum of the current I₃ and the current IP₁ (I_{2A}) is equal to the sum of the current IP₂ (I_{1A}), the current I₄, and the current I₇. Additionally, the current flowing out of the output terminal ON is the sum of the currents IN₂, I₆, and I₈. In this case, the sum of the current I₅ and the current IN₁ (I_{2B}) is equal to the sum of the current IN₂ (I_{1B}), the current I₆, and the current I₈.

In another embodiment, when the input signals IN and IP do not have data components and the voltages of the input signals IN and IP are lower than the second threshold value, the NMOS transistor pair 130 does not operates and the PMOS transistor pair 120 operates. At this time, the current control circuit 150 replaces the NMOS transistor pair 130 to provide the sub-current I_{2A} and the sub-current I_{2B} to the current modulator circuit 160. The current modulator circuit 160 further receives the sub-current I_{1A} and the sub-current I_{1B} from the PMOS transistor pair 120. At this time, the current flowing into the output terminal OP is the sum of the currents I₃ and IP₁. Since the current modulator circuit 160 provides the current IP₂, the current flowing out of the output terminal OP is the sum of the currents IP₂, I₄, and I₇. In this case, the sum of the current I₃ and the current IP₁ is equal to the sum of the current IP₂, the current I₄, and the current I₇. Additionally, the current flowing to the output terminal ON is the sum of the currents I₅ and IN₁, and the current flowing out of the output terminal ON is the sum of the currents IN₂, I₆, and I₈. In this case, the sum of the current I₅ and the current IN₁ is equal to the sum of the current IN₂, the current I₆, and the current I₈.

In some embodiments, when the input signals IN and IP do not have data components and the voltages of the input signals IN and IP are lower than the first threshold value and higher than the second threshold value, the PMOS transistor pair 120 and the NMOS transistor pair 130 operate. At this time, the current control circuits 140 and 150 do not operate. The current modulator circuit 160 receives the sub-currents I_{1A} and I_{1B} from the PMOS transistor pair 120 and the sub-current I_{2A} and I_{2B} from the NMOS transistor pair 130. At this time, the current flowing into the output terminal OP is the sum of the currents I₃ and IP₁. Since the current modulator circuit 160 provides the current IP₂, the current flowing out of the output terminal OP is the sum of the currents IP₂, I₄, and I₇. In this case, the sum of the current I₃ and the current IP₁ is equal to the sum of the current IP₂, the current I₄, and the current I₇. Additionally, the current flowing to the output terminal ON is the sum of the currents I₅ and IN₁, and the current flowing out of the output terminal ON is the sum of the currents IN₂, I₆, and I₈. In this case, the sum of the current I₅ and the current IN₁ is equal to the sum of the current IN₂, the current I₆, and the current I₈.

In this embodiment, the voltages of the input signals IN and IP are within the operation voltages VDD and GND. When the input signals IN and IP do not have data components, the static current of the output terminal OP and the static current of the output terminal ON are maintained. When the input signals IN and IP have data components, the output terminals OP and ON provide differential signals. Therefore, the differential signal generation circuit 100 serves as a constant current modulator and controller for rail-to-rail input range with differential outputs.

Furthermore, the current control circuits 140 and 150 are used so that the voltage range of the input signals IN and IP is not limited by the threshold voltages of transistors. For example, when the voltages of the input signals IN and IP are higher than a first threshold value, the PMOS transistor pair 120 does not operate to stop providing the sub-currents I_{1A} and I_{1B}. However, since the current control circuit 140 replaces the PMOS transistor pair 120 to provide the sub-currents I_{1A} and I_{1B}, the current modulator circuit 160 can receive the sub-currents I_{1A} and L_{1B}. Similarly, when the voltages of the input signals IN and IP are lower than a second threshold value, the NMOS transistor pair 130 does not operate to stop providing the sub-currents I_{2A} and I_{2B}. However, since the current control circuit 150 replaces the NMOS transistor pair 130 to provide the sub-currents I_{2A} and I_{2B}, the current modulator circuit 160 can receive the sub-currents I_{2A} and I_{2B}. Since the voltage range of the input signal of the differential signal generation circuit 100 is increased, the function of wide range rail-to-rail input voltage can be achieved.

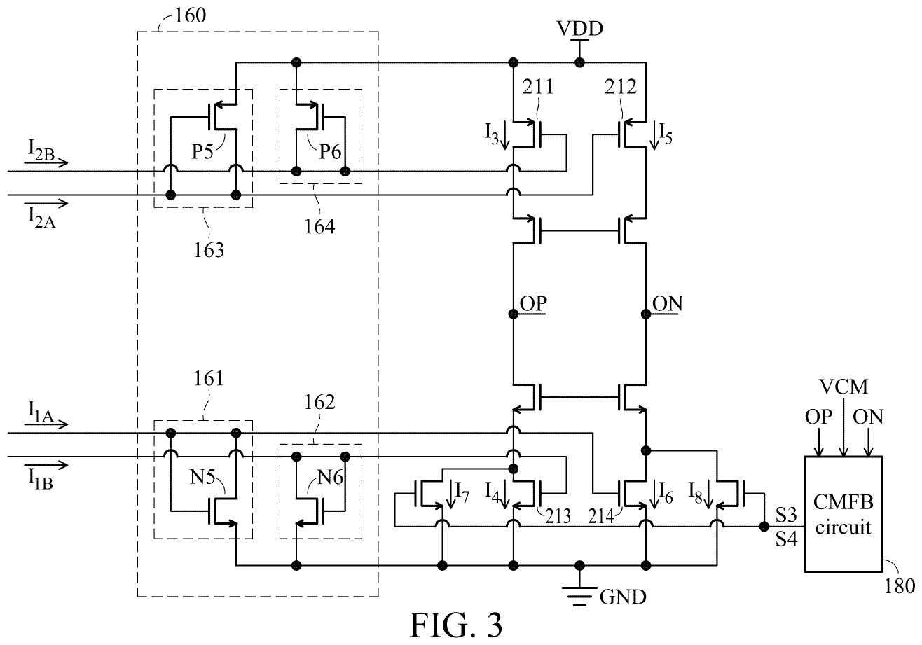

FIG. 3 is a schematic diagram of another exemplary embodiment of the current modulator circuit 160 based on various aspects of the present disclosure. In FIG. 3, the sub-currents I_{1A} and I_{1B} are provided by the PMOS transistor pair 120 or the current control circuit 140, and the sub-currents I_{2A} and I_{2B} are provided by the NMOS transistor pair 130 or the current control circuit 150. Since the circuit structures of the PMOS transistor pair 120, the NMOS transistor pair 130, and the current control circuits 140 and 150 are shown in FIG. 2, FIG. 3 does not show the circuit structures of the PMOS transistor pair 120, the NMOS transistor pair 130, and the current control circuits 140 and 150.

The current modulator circuit 160 comprises modulators 161 and 162. The modulator 161 receives the sub-current I_{1A} and the operation voltage GND. In this embodiment, the modulator 161 is an NMOS transistor N5. The gate and the drain of the NMOS transistor N5 receives the sub-current I_{1A} and are coupled to the gate of the NMOS transistor 214 which serves as the current source 116. The source of the NMOS transistor N5 receives the operation voltage GND. The modulator 161 and the NMOS transistor 214 constitute a first current mirror. In this case, the current I₆ passing through the NMOS transistor 214 is equal to the sub-current I_{1A} passing through the NMOS transistor N5.

The modulator 162 is an NMOS transistor N6. The gate and the drain of the NMOS transistor N6 receives the sub-current I_{1B} and are coupled to the gate of the NMOS transistor 213 which serves as the current source 114. The source of the NMOS transistor N6 receives the operation voltage GND. The modulator 162 and the NMOS transistor 213 constitute a second current mirror. In this case, the current I₄ passing through the NMOS transistor 213 is equal to the sub-current I_{1B} passing through the NMOS transistor N6.

In some embodiments, the current modulator circuit 160 further comprises modulators 163 and 164. The modulator 163 receives the sub-current I_{2A} and the operation voltage VDD. The modulator 163 is a PMOS transistor P5. The gate and the drain of the PMOS transistor P5 receives the sub-current I_{2A} and are coupled to the gate of the PMOS transistor 212 which serves as the current source 115. The source of the PMOS transistor P5 receives the operation voltage VDD. In this embodiment, the modulator 163 and the PMOS transistor 212 constitute a third current mirror. In this case, the current I₅ passing through the PMOS transistor 212 is equal to the sub-current I_{2A} passing through the PMOS transistor P5.

The modulator 164 is a PMOS transistor P6. The gate and the drain of the PMOS transistor P6 receives the sub-current I_{2B} and are coupled to the gate of the PMOS transistor 211 which serves as the current source 113. The source of the PMOS transistor P6 receives the operation voltage VDD. In this embodiment, the modulator 164 and the PMOS transistor 211 constitute a fourth current mirror. In this case, the current I₃ passing through the PMOS transistor 211 is equal to the sub-current I_{2B} passing through the PMOS transistor P6.

In some embodiments, when the input signals IN and IP do not have data components and the voltages of the input signals IN and IP are higher than the first threshold value, the PMOS transistor pair 120 does not operate and the NMOS transistor pair 130 operates. At this time, the current control circuit 140 replaces the PMOS transistor pair 120 to provide the sub-current I_{1A} and the sub-current I_{1B} to the current modulator circuit 160. The current modulator circuit 160 further receives the sub-current I_{2A} and the sub-current I_{2B} from the NMOS transistor pair 130. Since the PMOS transistor P6 and the PMOS transistor 211 constitute a current mirror, the current I₃ passing through the PMOS transistor 211 is equal to the sub-current I_{2B} passing through the PMOS transistor P6. At this time, the current flowing to the output terminal OP is the sub-current I_{2B}. Since the NMOS transistor N6 and the NMOS transistor 213 constitute another current mirror, the current I₄ passing through the NMOS transistor 213 is equal to the sub-current I_{1B} passing through the NMOS transistor N6. At this time, the current flowing out of the output terminal OP is the sum of the currents I_{1B} and I₇. In this case, the sub-current I_{2B} is the sum of the sub-current I_{1B} and the current I₇. Additionally, since the PMOS transistor P5 and the PMOS transistor 212 constitute a current mirror, the current I₅ passing through the PMOS transistor 212 is equal to the sub-current I_{2A} passing through the PMOS transistor P5. At this time, the current flowing to the output terminal ON is the sub-current I_{2A}. Since the NMOS transistor N5 and the NMOS transistor 214 constitute another current mirror, the current I₆ passing through the NMOS transistor 214 is equal to the sub-current I_{1A} passing through the NMOS transistor N5. At this time, the current flowing out of the output terminal ON is the sum of the sub-current I_{1A} and the current I₈. In this case, the sub-current I_{2A} is the sum of the sub-current I_{1A} and the current I₈.

When the input signals IN and IP do not have data components and the voltages of the input signals IN and IP are lower than the first threshold value and higher than the second threshold value, the PMOS transistor pair 120 and the NMOS transistor pair 130 operate. At this time, the current control circuits 140 and 150 stop working. The current modulator circuit 160 receives the sub-current I_{1A} and the sub-current I_{1B} from the PMOS transistor pair 120 and the sub-current I_{2A} and the sub-current I_{2B} from the NMOS transistor pair 130. Therefore, the current flowing to the output terminal ON is equal to the sub-current I_{2A}, and the current flowing out of the output terminal ON is the sum of the sub-current I_{1A} and the current I₈.

In this embodiment, regardless of the voltages of the input signals IN and IP, the static currents of the output terminals OP and ON remain unchanged. Furthermore, the voltage ranges of the input signals IN and IP are not limited by the threshold voltages of the transistors. Therefore, the voltage range of the input signal of the differential signal generation circuit 100 is increased to achieve the function of a wide range rail-to-rail input voltage.

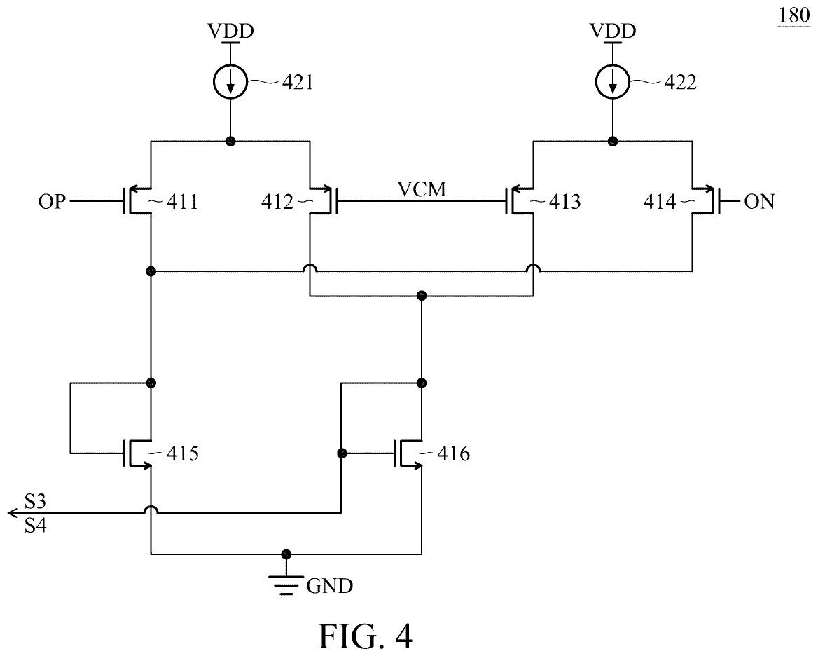

FIG. 4 is a schematic diagram of an exemplary embodiment of the CMFB circuit 180 based on various aspects of the present disclosure. The CMFB circuit 180 comprises PMOS transistors 411-414, NMOS transistors 415 and 416, and current sources 421 and 422. The current source 421 receives the operation voltage VDD and is coupled to the PMOS transistors 411 and 412. The current source 422 receives the operation voltage VDD and is coupled to the PMOS transistors 413 and 414.

The gate of the PMOS transistor 411 is coupled to the output terminal OP. The source of the PMOS transistor 411 is coupled to the current source 421. The drain of the PMOS transistor 411 is coupled to the drain of the PMOS transistor 414 and the drain of the NMOS transistor 415. The gate of the PMOS transistor 412 receives the common-mode voltage VCM. The source of the PMOS transistor 412 is coupled to the current source 421. The drain of the PMOS transistor 412 is coupled to the drain of the PMOS transistor 413 and the drain of the NMOS transistor 416. The gate of the PMOS transistor 413 receives the common-mode voltage VCM. The source of the PMOS transistor 413 is coupled to the current source 422. The gate of the PMOS transistor 414 is coupled to the output terminal ON. The source of the PMOS transistor 414 is coupled to the current source 422.

The gate of the NMOS transistor 415 is coupled to the drain of the PMOS transistor 411. The source of the NMOS transistor 415 receives the operation voltage GND. The gate of the NMOS transistor 416 is coupled to the drain of the PMOS transistor 415 and provides the adjustment signals S3 and S4. In this case, the adjustment signal S3 is the same as the adjustment signal S4. The source of the NMOS transistor 416 receives the operation voltage GND.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another. In the following claims, the terms “first,” “second,” etc. are used merely as labels, and are not intended to impose numerical requirements on their objects.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). For example, it should be understood that the system, device and method may be realized in software, hardware, firmware, or any combination thereof. Therefore, the scope of the appended claims should be accorded the broadest interpretation so as to encompass all such modifications and similar arrangements.

What is claimed is:

1. A differential signal generation circuit, comprising:
a first current source receiving a first operation voltage to generate a first current;
a current modulator circuit adjusting a current of a first output terminal and a current of a second output terminal;
a PMOS transistor pair coupled between the first current source and the current modulator circuit to provide the first current to the current modulator circuit and receiving a first input signal and a second input signal;
a first current control circuit coupled to the PMOS transistor pair in parallel, wherein in response to the PMOS transistor pair being turned off, the first current control circuit transmits the first current to the current modulator circuit;
a second current source receiving a second operation voltage to generate a second current;
an NMOS transistor pair coupled between the current modulator circuit and the second current source to provide the second current to the current modulator circuit and receiving the first input signal and the second input signal;
a second current control circuit coupled to the NMOS transistor pair in parallel, wherein in response to the NMOS transistor pair being turned off, the second current control circuit transmits the second current to the current modulator circuit;
a third current source receiving the first operation voltage and coupled to the first output terminal;
a fourth current source coupled to the first output terminal and receiving the second operation voltage;
a fifth current source receiving the first operation voltage and coupled to the second output terminal;
a sixth current source coupled to the second output terminal and receiving the second operation voltage; and
a common-mode feedback (CMFB) circuit adjusting the third current source or the fourth current source based on a voltage of the first output terminal and a common-mode voltage and adjusting the fifth current source or the sixth current source based on a voltage of the second output terminal and the common-mode voltage, and
wherein:
in response to the first current control circuit being in operation, the current modulator circuit provides a first sub-current to the first output terminal and provides a second sub-current to the second output terminal,
in response to the second current control circuit being in operation, the current modulator circuit provides a third sub-current to the first output terminal and provides a fourth sub-current to the second output terminal, and
a first sum of the first sub-current and the second sub-current is equal to the first current, and a second sum of the third sub-current and the fourth sub-current is equal to the second current.

2. The differential signal generation circuit as claimed in claim 1, wherein:
the PMOS transistor pair comprises:
a first PMOS transistor comprising a gate receiving the first input signal, a source coupled to the first current source, and a drain coupled to the current modulator circuit; and
a second PMOS transistor comprising a gate receiving the second input signal, a source coupled to the first current source, and a drain coupled to the current modulator circuit;
the NMOS transistor pair comprises:
a first NMOS transistor comprising a gate receiving the first input signal, a source coupled to the second current source, and a drain coupled to the current modulator circuit; and
a second NMOS transistor comprising a gate receiving the second input signal, a source coupled to the second current source, and a drain coupled to the current modulator circuit.

3. The differential signal generation circuit as claimed in claim 2, wherein the first current control circuit comprises:
a third PMOS transistor comprising a gate receiving a first control voltage, a source coupled to the first current source, and a drain coupled to the drain of the first PMOS transistor; and
a fourth PMOS transistor comprising a gate receiving the first control voltage, a source coupled to the first current source, and a drain coupled to the drain of the second PMOS transistor.

4. The differential signal generation circuit as claimed in claim 3, wherein:
in response to the first PMOS transistor being turned on, the first PMOS transistor provides the first sub-current to the current modulator circuit,
in response to the third PMOS transistor being turned on, the third PMOS transistor provides the first sub-current to the current modulator circuit,
in response to the second PMOS transistor being turned on, the second PMOS transistor provides the second sub-current to the current modulator circuit,
in response to the fourth PMOS transistor being turned on, the fourth PMOS transistor provides the second sub-current to the current modulator circuit.

5. The differential signal generation circuit as claimed in claim 3, wherein the second current control circuit comprises:
a third NMOS transistor comprising a gate receiving a second control voltage, a source coupled to the second current source, and a drain coupled to the drain of the first NMOS transistor; and
a fourth NOMS transistor comprising a gate receiving the second control voltage, a source coupled to the second current source, and a drain coupled to the drain of the second NMOS transistor.

6. The differential signal generation circuit as claimed in claim 5, wherein the second control voltage is higher than the second operation voltage and lower than the first control voltage.

7. The differential signal generation circuit as claimed in claim 5, wherein:
in response to the first NMOS transistor being turned on, the first NMOS transistor provides the third sub-current to the current modulator circuit,
in response to the third NMOS transistor being turned on, the third NMOS transistor provides the third sub-current to the current modulator circuit,
in response to the second NMOS transistor being turned on, the second NMOS transistor provides the fourth sub-current to the current modulator circuit, and
in response to the fourth NMOS transistor being turned on, the fourth NMOS transistor provides the fourth sub-current to the current modulator circuit.

8. The differential signal generation circuit as claimed in claim 5, wherein the current modulator circuit comprises:
a first modulator coupled to the first PMOS transistor and receiving the second operation voltage; and
a second modulator coupled to the second PMOS transistor and receiving the second operation voltage, and
wherein the first modulator and the sixth current source constitute a first current mirror, and the second modulator and the fourth current source constitute a second current mirror.

9. The differential signal generation circuit as claimed in claim 8, wherein:
the first modulator is a fifth NMOS transistor, and the second modulator is a sixth NMOS transistor,
a gate and a drain of the fifth NMOS transistor are coupled to the drain of the first PMOS transistor and the sixth current source, and a source of the fifth NMOS transistor receives the second operation voltage,
a gate and a drain of the sixth NMOS transistor are coupled to the drain of the second PMOS transistor and the fourth current source, and a source of the sixth NMOS transistor receives the second operation voltage.

10. The differential signal generation circuit as claimed in claim 8, wherein the current modulator circuit further comprises:
a third modulator coupled to the first NMOS transistor and receiving the first operation voltage; and
a fourth modulator coupled to the second NMOS transistor and receiving the first operation voltage, and
wherein the third modulator and the fifth current source constitute a third current mirror, and the fourth modulator and the third current source constitute a fourth current mirror.

11. The differential signal generation circuit as claimed in claim 10, wherein a current generated by the fourth current source is equal to the second sub-current, a current generated by the sixth current source is equal to the first sub-current, a current generated by the fifth current source is equal to the third sub-current, and a current generated by the third current source is equal to the fourth sub-current.

12. The differential signal generation circuit as claimed in claim 10, wherein:
the third modulator is a fifth PMOS transistor, and the fourth modulator is a sixth PMOS transistor,
a gate and a drain of the fifth PMOS transistor are coupled to the drain of the first NMOS transistor and the fifth current source, and a source of the fifth PMOS transistor receives the first operation voltage, and
a gate and a drain of the sixth PMOS transistor are coupled to the drain of the second NMOS transistor and the third current source, and a source of the sixth PMOS transistor receives the first operation voltage.

13. The differential signal generation circuit as claimed in claim 1, further comprising:
a seventh PMOS transistor coupled between the third current source and the first output terminal;
an eighth PMOS transistor coupled between the fifth current source and the second output terminal;
a seventh NMOS transistor coupled between the first output terminal and the fourth current source; and
an eighth NMOS transistor coupled between the second output terminal and the sixth current source,
wherein a gate of the seventh PMOS transistor is coupled to a gate of the eighth PMOS transistor, and a gate of the seventh NMOS transistor is coupled to a gate of the eighth NMOS transistor.

14. The differential signal generation circuit as claimed in claim 13, wherein in response to the first input signal being equal to the second input signal, the voltage of the first output terminal and the voltage of the second output terminal are equal to the common-mode voltage.

15. The differential signal generation circuit as claimed in claim 14, wherein in response to the first input signal and the second input signal being higher than a first threshold value:
the PMOS transistor pair stops providing the first current to the current modulator circuit,
the second current control circuit stops providing the second current to the current modulator circuit,
the NMOS transistor pair provides the second current to the current modulator circuit, and
the first current control circuit provides the first current to the current modulator circuit.

16. The differential signal generation circuit as claimed in claim 15, wherein in response to the first input signal and the second input signal being lower than a second threshold value:
the NMOS transistor pair stops providing the second current to the current modulator circuit,
the first current control circuit stops providing the first current to the current modulator circuit,
the PMOS transistor pair provides the first current to the current modulator circuit, and
the second current control circuit provides the second current to the current modulator circuit.

17. The differential signal generation circuit as claimed in claim 16, wherein in response to the first input signal and the second input signal being between the first threshold value and the second threshold value:
the first current control circuit stops providing the first current to the current modulator circuit,
the second current control circuit stops providing the second current to the current modulator circuit,
the PMOS transistor pair provides the first current to the current modulator circuit, and
the NMOS transistor pair provides the second current to the current modulator circuit.

18. The differential signal generation circuit as claimed in claim 17, wherein in response to the first input signal being lower than the first operation voltage and higher than the second threshold value, the second threshold value is higher than the second operation voltage.

19. The differential signal generation circuit as claimed in claim 17, wherein in response to the first input signal and the second input signal being between the first operation voltage and the second operation voltage, a static current of the first output terminal is equal to a static current of the second output terminal.

20. The differential signal generation circuit as claimed in claim 13, further comprising:
a seventh current source coupled to the fourth current source in parallel; and
an eighth current source coupled to the sixth current source in parallel,
wherein the CMFB circuit adjusts the seventh current source based on the voltage of the first output terminal and the common-mode voltage, and adjusts the eighth current source based on the voltage of the second output terminal and the common-mode voltage.
